(19) United States
(12) Patent Application Publication
(10) Pub. No.: US 2026/0255991 A1
(43) Pub. Date: Aug. 27, 2026

(54) SEMICONDUCTOR PACKAGE

(71) Applicant: Samsung Electronics Co., Ltd., Suwon-si (KR)

(72) Inventors: Jongyoun Kim, Suwon-si (KR); Sangkyu Lee, Suwon-si (KR)

(73) Assignee: Samsung Electronics Co., Ltd., Suwon-si (KR)

(21) Appl. No.: 19/337,241

(22) Filed: Sep. 23, 2025

(30) Foreign Application Priority Data
Feb. 21, 2025 (KR) 10-2025-0023012

(51) Int. Cl. H01L 23/00; H01L 21/56; H01L 23/31; H01L 23/538; H01L 25/065

(52) U.S. Cl. CPC H10W 70/611; H10W 74/121; H10W 90/00; H10W 90/401; H10W 72/877; H10W 74/014; H10W 74/15; H10W 90/20; H10W 90/24; H10W 90/724; H10W 90/732; H10W 90/734

(57) ABSTRACT

Provided is a semiconductor package including a package substrate, a plurality of chip modules stacked in a stair structure on the package substrate in a first direction substantially perpendicular to a front side surface of the package substrate, a capping layer surrounding the plurality of chip modules, and a plurality of interconnection modules extending in the first direction by penetrating the capping layer on back side surfaces of the plurality of chip modules, and configured to electrically connect the package substrate and at least one of the plurality of chip modules, wherein each of the plurality of interconnection modules includes an interconnection molding film surrounded by the capping layer, and a plurality of interconnection posts penetrating the interconnection molding film, and wherein the plurality of chip modules include a plurality of chips stacked in a stair structure.

### CROSS-REFERENCE TO RELATED APPLICATIONS

This present application claims priority to and the benefit under 35 U.S.C. § 119(a)-(d) of Korean Patent Application No. 10-2025-0023012, filed on Feb. 21, 2025, in the Korean Intellectual Property Office, the entire disclosure of which is incorporated herein by reference.

### FIELD

Example embodiments relate to a semiconductor package.

### BACKGROUND

Due to advancements in the electronics industry, demand for high functionality, high speed and miniaturization of electronic components is increasing. In response to this tendency, a method of stacking and mounting multiple semiconductor chips in a single package wiring structure or stacking packages on top of packages may be used. For example, a package-in-package (PIP) type of semiconductor package or a package-on-package (POP) type of semiconductor package may be used.

Meanwhile, with the high integration of semiconductor packages, a vertical wiring structure in which semiconductor chips are stacked vertically and the semiconductor chips are electrically connected is used.

### SUMMARY

Aspects provide a semiconductor package that can stack a semiconductor chip by high stages.

Aspects provide a semiconductor package including a modularized post according to various stacked numbers.

Technical goals of the present disclosure are not limited to the aforementioned technical goals, and other unstated technical goals may be clearly understood by those who skilled in the art from descriptions below.

According to aspects, there is provided a semiconductor package including a package substrate, a plurality of chip modules stacked in a stair structure on the package substrate in a first direction substantially perpendicular to a front side surface of the package substrate, a capping layer surrounding the plurality of chip modules, and a plurality of interconnection modules extending in the first direction by penetrating the capping layer on back side surfaces of the plurality of chip modules, and that are configured to electrically connect at least one of the plurality of chip modules and the package substrate, wherein each of the plurality of interconnection modules includes an interconnection molding film surrounded by the capping layer, and a plurality of interconnection posts penetrating the interconnection molding film, and wherein the plurality of chip modules include a plurality of chips stacked in a stair structure.

According to aspects, there is provided a semiconductor package including a package substrate, a first chip module to a fourth chip module stacked in a stair structure on the package substrate in a first direction substantially perpendicular to a front side surface of the package substrate, a capping layer surrounding the first chip module, a second chip module, a third chip module and the fourth chip module, and a plurality of interconnection modules extending in the first direction by penetrating the capping layer, and that are configured to electrically connect the package substrate and each of the first chip module to the fourth chip module, wherein the first chip module includes at least one first chip placed to be spaced apart from the package substrate in the first direction perpendicular to the front side surface of the package substrate, a first chip molding film surrounding the first chip, and a first wiring post penetrating the first chip molding film in the first direction and connected with the first chip, wherein the second chip module includes at least one second chip placed on a back side surface of the first chip module and placed between the package substrate and the first chip module, a second chip molding film surrounding the second chip, and a second wiring post penetrating the second chip molding film in the first direction and connected with the second chip, wherein the third chip module includes at least one third chip placed on a back side surface of the second chip module and placed between the package substrate and the second chip module, a third chip molding film surrounding the third chip, and a third wiring post penetrating the third chip molding film in the first direction and connected with the third chip, and wherein the fourth chip module includes at least one fourth chip placed on a back side surface of the third chip module and placed between the package substrate and the third chip module, a fourth chip molding film surrounding the fourth chip, and a fourth wiring post penetrating the fourth chip molding film in the first direction and connected with the fourth chip.

According to aspects, there is provided a semiconductor package including, a package substrate, a first chip module to a fourth chip module stacked in a stair structure on the package substrate in a first direction substantially perpendicular to a front side surface of the package substrate, a capping layer surrounding the first chip module to the fourth chip module, and a plurality of interconnection modules extending in the first direction by penetrating the capping layer on a back side surface of each of the first chip module to a third chip module, and configured to electrically connect the package substrate and the first chip module to the third chip module, wherein at least one of the plurality of interconnection modules has a length in the first direction that is different from a length of each of a portion of the plurality of interconnection modules, and wherein levels of lowest surfaces of the plurality of interconnection modules are identical.

According to aspects, there is provided a manufacturing method of a semiconductor package, including stacking a plurality of chips on a base substrate in a stair structure in a first direction substantially perpendicular to a front side surface of the base substrate, forming a plurality of wiring posts to correspond to each of the plurality of chips at a stair area which is one side of the plurality of chips, forming a chip molding film surrounding the plurality of wiring posts and the plurality of chips, cutting a plurality of chip modules including the plurality of chips, the plurality of wiring posts and the chip molding film from the base substrate, stacking the plurality of chip modules on a carrier substrate in a stair structure, placing each of a plurality of interconnection modules to overlap at least a portion of the plurality of wiring posts in the first direction on the plurality of chip modules, forming a capping layer surrounding each of the plurality of chip modules and the plurality of interconnection modules, forming a package substrate on the plurality of chip modules, the plurality of interconnection modules and the capping layer, and removing the carrier substrate.

According to aspects, there is provided the manufacturing method of the semiconductor package, further including, before placing each of the plurality of interconnection modules, forming the plurality of interconnection modules including forming an interconnection molding layer, forming a recessed area penetrating at least a part of the interconnection molding layer in the first direction and forming an interconnection post on the recessed area.

Specific details of other example embodiments are included in the detailed description and drawings.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a drawing for illustrating a semiconductor package according to example embodiments of the present disclosure;

FIG. 2 is a drawing for illustrating a semiconductor package according to example embodiments of the present disclosure;

FIG. 3 is a drawing for illustrating a semiconductor package according to example embodiments of the present disclosure;

FIG. 4 is a drawing for illustrating a semiconductor package according to example embodiments of the present disclosure;

FIG. 5 is an exemplary drawing that illustrates by enlarging example embodiments of an area B of FIG. 4;

FIG. 6 is a drawing for illustrating a semiconductor package according to example embodiments of the present disclosure;

FIG. 7 is a drawing for illustrating a semiconductor package according to example embodiments of the present disclosure;

FIG. 8 is a drawing for illustrating a semiconductor package according to example embodiments of the present disclosure;

FIG. 9 is a drawing for illustrating a semiconductor package according to example embodiments of the present disclosure; and

FIGS. 10 to 18 are drawings illustrating, in a process order, examples of a manufacturing method of a semiconductor package according to example embodiments of the present disclosure.

### DETAILED DESCRIPTION

Before describing example embodiments in detail, the words and terminologies used in the specification and claims are not to be construed as limited to common or dictionary meanings but construed as meanings and concepts coinciding with the technical idea of the present disclosure under the principle that the inventor(s) may appropriately define the concept of the terms to explain his or her own invention in the best manner. Therefore, the example embodiments described herein and the configurations illustrated in the drawings are only the most desirable example embodiment of the present disclosure and do not fully cover the technical idea of the present disclosure, and thus, it should be understood that various equivalents and modification examples may be present as alternatives thereto when this application is filed.

In the following description, a singular expression includes a plural expression unless apparently otherwise defined by context. It should be understood that terms such as “comprise or include” and “form” are intended to indicate the presence of a feature, a number, a step, an operation, an element, a component or a combination thereof described in the specification and not intended to exclude the possibility of the presence or addition of one or more other features, numbers, steps, operations, elements, components or combinations thereof in advance.

In addition, it is clarified in advance that expressions such as upper side, upper portion, lower side, lower portion, side surface, front surface and rear surface are represented hereinafter with respect to a direction illustrated in a drawing and may be represented otherwise when the direction of a corresponding object changes. The shapes, sizes and the like of elements may be exaggerated in the drawings for clearer description.

Hereinafter, example embodiments according to the technical spirit of the present disclosure will be described with reference to the accompanying drawings.

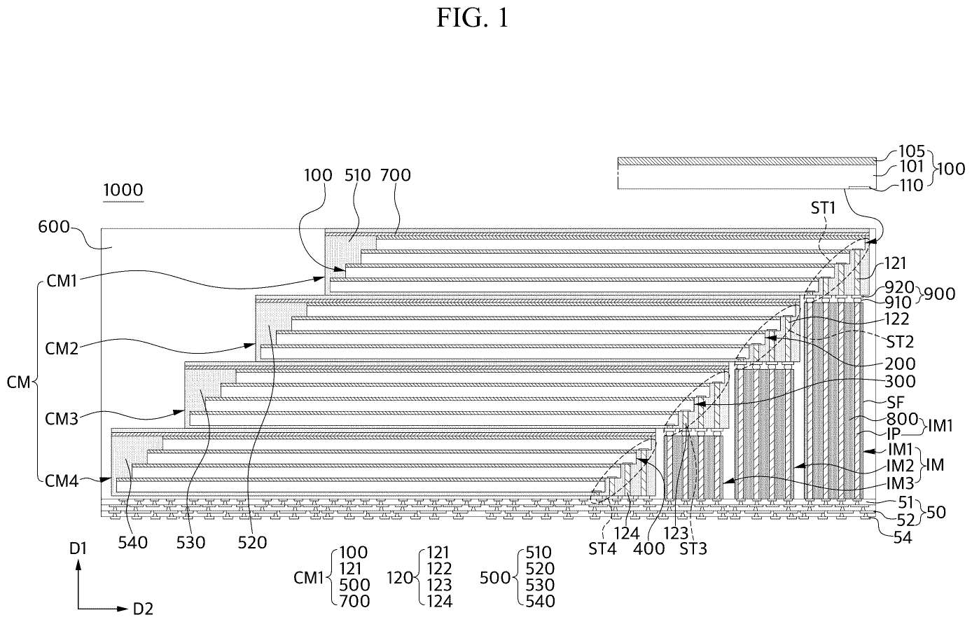

FIG. 1 is a diagram for illustrating a semiconductor package according to an example embodiment.

Referring to FIG. 1, a semiconductor package 1000 according to example embodiments includes a package substrate 50, a first chip module CM1, a second chip module CM2, a third chip module CM3, a fourth chip module CM4, a capping layer 600 and a plurality of interconnection modules IM.

According to example embodiments, the package substrate 50 may be a wiring structure for a package. For example, the package substrate 50 may be a printed circuit board (PCB), a ceramic substrate or an interposer. Alternatively, it is also apparent that the package substrate 50 may be a wiring structure for a wafer level package (WLP) manufactured at a wafer level. The package substrate 50 may be a semiconductor chip including a semiconductor device. The package substrate 50 may function as a support substrate of a semiconductor package.

In example embodiments, the package substrate 50 may be a glass substrate, a ceramic substrate or a plastic substrate, but the package substrate 50 is not limited thereto. As an example, the package substrate 50 may include a resin (e.g., prepreg, Ajinomoto build-up film (ABF), FR-4 or bismaleimide triazine (BT)) impregnated together with an inorganic filler in a core material such as a glass fiber (e.g., a glass cloth or a glass fabric).

According to example embodiments, the package substrate 50 may include, as an example, bulk silicon or silicon-on-insulator (SOI). As another example, the package substrate 50 may be a silicon substrate. As another example, the package substrate 50 may include silicon germanium, silicon germanium on insulator (SGOI), indium antimonide, a lead telluride compound, indium arsenide, indium phosphide, gallium arsenide or gallium antimonide. However, the package substrate 50 is not limited thereto.

According to example embodiments, the package substrate 50 may include a conductive area, for example, a well doped with an impurity or a structure doped with an impurity. The package substrate 50 may have various element isolation structures such as a shallow trench isolation (STI) structure.

According to example embodiments, the package substrate 50 may include a substrate body part 51 and a substrate wiring structure 52.

According to example embodiments, when the package substrate 50 is the PCB, the substrate body part 51 may be constituted with at least one material selected from a phenolic resin, an epoxy resin and polyimide. The package substrate 50 may include at least one material selected from tetrafunctional epoxy, polyphenylene ether, epoxy/polyphenylene oxide, BT, Thermount, cyanate ester and a liquid crystal polymer.

According to example embodiments, the substrate body part 51 may include a photoimageable dielectric. As an example, the substrate body part 51 may include a photoimageable polymer. The photoimageable polymer may be constituted with, for example, at least one of photoimageable polyimide, polybenzoxazole, a phenolic polymer and a benzocyclobutene-based polymer. As another example, the substrate body part 51 may be constituted with a silicon oxide film, a silicon nitride film or a silicon oxynitride film.

According to example embodiments, a surface of the substrate body part 51 may be covered with solder resist although not illustrated. For example, a passivation film may be formed on the surface of the substrate body part 51. The passivation film formed on the surface of the substrate body part 51 may protect the substrate wiring structure 52 and other structures from external impact or moisture. The passivation film may include the solder resist. However, the technical idea of the present disclosure is not limited thereto.

According to example embodiments, the substrate wiring structure 52 may be placed in the substrate body part 51. The substrate wiring structure 52 may include wiring patterns and wiring vias that connect each wiring pattern. For example, the substrate wiring structure 52 may be a multilayer structure in which two or more wiring patterns or two or more wiring vias are alternatingly stacked. For example, the wiring pattern may extend in a second direction D2. The wiring via may connect the wiring patterns spaced apart in a first direction D1. Here, the first direction D1 may refer to a direction perpendicular to a surface of the package substrate 50. For example, the first direction D1 may indicate a direction perpendicular to a front side surface of a package substrate or a back side surface of a package substrate.

In example embodiments, the substrate wiring structure 52 may include a conductive material. For example, the substrate wiring structure 52 may include copper (Cu), aluminum (Al), silver (Ag), tin (Sn), gold (Au), nickel (Ni), lead (Pb), titanium (Ti) or an alloy thereof, but the same is not limited thereto.

According to example embodiments, a plurality of chip modules CM include the first chip module CM1, the second chip module CM2, the third chip module CM3 and the fourth chip module CM4 stacked in a stair structure on a front side surface of the package substrate 50 in the first direction D1 perpendicular to the front side surface of the package substrate 50. The first chip module CM1, the second chip module CM2, the third chip module CM3 and the fourth chip module CM4 stacked in a stair structure may be placed by being offset at a predetermined interval in the second direction D2.

According to example embodiments, each of the first chip module CM1, the second chip module CM2, the third chip module CM3 and the fourth chip module CM4 may include at least one chip (e.g., a first chip 100, a second chip 200, a third chip 300 and a fourth chip 400), a chip molding film 500 surrounding the first chip 100, the second chip 200, the third chip 300 and the fourth chip 400, and a wiring post 120 extending in the first direction D1 by penetrating the chip molding film 500 and electrically connected with the first chip 100, the second chip 200, the third chip 300 and the fourth chip 400.

According to example embodiments, the first chip module CM1 may include at least one first chip 100 placed to be spaced apart from the package substrate 50 in the first direction D1 perpendicular to the front side surface of the package substrate 50, a first chip molding film 510 surrounding the first chip 100 and a first wiring post 121 penetrating the first chip molding film 510 in the first direction D1 and connected with the first chip 100.

According to example embodiments, the second chip module CM2 may include at least one second chip 200 placed on a back side surface of the first chip module CM1 and placed between the package substrate 50 and the first chip module CM1, a second chip molding film 520 surrounding the second chip 200, and a second wiring post 122 penetrating the second chip molding film 520 in the first direction D1 and connected with the second chip 200.

According to example embodiments, the third chip module CM3 may include at least one third chip 300 placed on a back side surface of the second chip module CM2 and placed between the package substrate 50 and the second chip module CM2, a third chip molding film 530 surrounding the third chip 300, and a third wiring post 123 penetrating the third chip molding film 530 in the first direction and connected with the third chip 300.

According to example embodiments, the fourth chip module CM4 may include at least one fourth chip 400 placed on a back side surface of the third chip module CM3 and placed between the package substrate 50 and the third chip module CM3, a fourth chip molding film 540 surrounding the fourth chip 400, and a fourth wiring post 124 penetrating the fourth chip molding film 540 in the first direction D1 and connected with the fourth chip 400.

According to example embodiments, the first chip module CM1 may be placed on the package substrate 50 in the first direction D1. The first chip module CM1 may be placed on the second chip module CM2 in the first direction D1. The first chip module CM1 may be placed to be further spaced apart from the package substrate 50 compared to the second chip module CM2 in the first direction D1.

According to example embodiments, the first chip module CM1 may include at least one first chip 100. For example, the first chip module CM1 may include the plurality of first chips 100. For example, the first chip module CM1 may include four of the first chips 100. The first chips 100 may be placed on the package substrate 50 in the first direction D1. FIG. 1 illustrates that the first chip module CM1 includes four of the first chips 100, but example embodiments are not limited thereto. For example, it is also apparent that the first chip module CM1 may include only one of the first chip 100 or may include five or more of the first chips 100.

For example, the plurality of first chips 100 through fourth chips 400) may be placed by being offset with one another in stair areas (e.g., a first stair area ST1, a second stair area ST2, a third stair area ST3 and a fourth stair area ST4) in the second direction D2. Being placed by being offset may signify being placed to be staggered at a predetermined interval. For example, the plurality first chips 100 through fourth chips 400) may not be placed to completely overlap one another in the first direction D1 in order for a portion thereof to overlap in the first direction D1, and a remaining portion thereof to be placed to be staggered in the second direction D2 so as not to overlap in the first direction D1. Side walls of the plurality of first chips 100 may be placed to be spaced apart at uniform intervals without being placed on the same plane with one another. Because the plurality of first chips 100 through fourth chips 400) may be placed to be offset in the second direction D2, a connection pad 110 placed at each of a portion of the plurality of first chips 100 through fourth chips 400) may not overlap another portion of the plurality of first chips 100 through the fourth chips 400) in the first direction D1. Therefore, the connection pad 110 may be individually connected with the first wiring post 121, the second wiring post 122, the third wiring post 123 and the fourth wiring post 124.

According to example embodiments, the chip molding film 500 may surround the first chip 100, the second chip 200, the third chip 300 and the fourth chip 400. The chip molding film 500 may surround the wiring post 120. The chip molding film 500 may form an interface with the capping layer 600. The chip molding film 500 may include an insulation material. As an example, the chip molding film 500 may include an insulating high-polymer material such as an epoxy molding compound (EMC). As another example, the chip molding film 500 may include a thermosetting resin such as an epoxy resin or a thermoplastic resin such as polyimide. The chip molding film 500 may include a filler. A content of the filler individually included in the chip molding film 500 of the first chip module CM1, the second chip module CM2, the third chip module CM3 and the fourth chip module CM4 may vary.

For instance, the chip molding film 500 may include a thermosetting resin such as an epoxy resin, a thermoplastic resin such as polyimide, or a prepreg, ABF, FR-4, BT, and an EMC including an inorganic filler or/and a glass fiber.

According to example embodiments, the wiring post 120 may be placed between the first chip 100 through the fourth chip 400 and a first interconnection module IM1 through a third interconnection module IM3. The wiring post 120 may extend between the first chip 100 through the fourth chip 400 and the first interconnection module IM1 through the third interconnection module IM3 in the first direction D1. The wiring post 120 may penetrate the chip molding film 500. The wiring post 120 may be configured to electrically connect an interconnection post IP and the first chip 100 through the fourth chip 400. The wiring post 120 may include a metallic material such as titanium (Ti), copper (Cu), aluminum (Al), silver (Ag), tin (Sn), gold (Au), nickel (Ni), lead (Pb) or an alloy thereof. FIG. 1 illustrates that the wiring post 120 is a single-layered film, but example embodiments are not limited thereto. For example, the wiring post 120 may include a multilayered film structure.

According to example embodiments, each of the plurality of chips (e.g., the first chip 100, the second chip 200, the third chip 300 and the fourth chip 400) may include an insulation film 101, an adhesive layer 105 and a connection pad 110. Each of the plurality of chips (e.g., the first chip 100, the second chip 200, the third chip 300 and the fourth chip 400) may be placed by being offset with one another at the stair areas (the first stair area ST1, the second stair area ST2, the third stair area ST3 and the fourth stair area ST4).

According to example embodiments, the insulation film 101 may include, for example, a photoimageable dielectric. For example, the insulation film 101 may include a photoimageable polymer. The photoimageable polymer may be constituted with, for example, at least one of photoimageable polyimide, polybenzoxazole, a phenolic polymer and a benzocyclobutene-based polymer. As another example, the insulation film 101 may be constituted with a silicon oxide film, a silicon nitride film or a silicon oxynitride film.

According to example embodiments, the adhesive layer 105 may include a non-conductive film (NCF), a non-conductive paste (NCP), an insulating polymer or an epoxy resin. However, the technical idea of the present disclosure is not limited thereto. For example, the adhesive layer 105 may be a tape configured to fix the first chip 100, the second chip 200, the third chip 300 and the fourth chip 400 to one another. The adhesive layer 105 may be a tape including an epoxy component, for example.

According to example embodiments, the connection pad 110 may be placed at a lower surface of each of the first chip 100, the second chip 200, the third chip 300 and the fourth chip 400. Here, the lower surface of each of the first chip 100, the second chip 200, the third chip 300 and the fourth chip 400 may refer to one surface of each of the first chip 100, the second chip 200, the third chip 300 and the fourth chip 400 facing the package substrate 50. The connection pad 110 may be exposed at a surface of each of the first chip 100, the second chip 200, the third chip 300 and the fourth chip 400. The connection pad 110 may be in contact with the first wiring post 121, the second wiring post 122, the third wiring post 123 and the fourth wiring post 124. The connection pad 110 may be configured to be electrically connected with the interconnection module IM by means of the wiring posts 120 which are to be described hereinafter, and may receive an electric signal inputted from an external connection terminal 55, but the same is not limited thereto.

According to example embodiments, each of the plurality of chips (e.g., the first chip 100, the second chip 200, the third chip 300 and the fourth chip 400) may include an integrated circuit (IC). Each of the plurality of chips (e.g., the first chip 100, the second chip 200, the third chip 300 and the fourth chip 400) may have an active surface on which the IC is formed and an inactive surface placed at the opposite side to the active surface. The active surface may be referred to as a front side surface, and the inactive surface may be referred to as a back side surface. For example, the front side surface may refer to a surface facing the package substrate 50. The inactive surface may refer to a surface that is placed at the opposite side to the front side surface.

According to example embodiments, each of the plurality of chips (e.g., the first chip 100, the second chip 200, the third chip 300 and the fourth chip 400) may be a memory semiconductor chip. The memory semiconductor chip may be a volatile memory such as a dynamic random access memory (DRAM) or a static random access memory (SRAM), for example. Alternatively, the memory semiconductor chip may also be a non-volatile memory such as a flash memory, a phase-change random access memory (PRAM), a magnetic random access memory (MRAM), a ferroelectric random access memory (FeRAM) or a resistive random access memory (RRAM). However, example embodiments are not limited thereto.

For example, at least a portion of the plurality of chips (e.g., the first chip 100, the second chip 200, the third chip 300 and the fourth chip 400) may be a logic semiconductor chip. The logic semiconductor chip may be, for example, an application processor (AP) such as a central processing unit (CPU), a graphic processing unit (GPU), a field-programmable gate array (FPGA), a digital signal processor, a cryptographic processor, a microprocessor, a microcontroller and an application-specific IC (ASIC).

According to example embodiments, each of the plurality of chip modules CM may include a passivation layer 700 on a front side surface of a chip located on a top portion among the plurality of chips (e.g., the first chip 100, the second chip 200, the third chip 300 and the fourth chip 400). The front side surface of the chip may refer to a surface placed at the opposite side to a back side surface of a chip facing the package substrate 50.

According to example embodiments, the capping layer 600 may include an insulation material. As an example, the capping layer 600 may include an insulating high-polymer material such as an EMC. As another example, the same may include a thermosetting resin such as an epoxy resin, a thermoplastic resin such as polyimide, or a prepreg, ABF, FR-4, BT and an EMC including an inorganic filler or/and a glass fiber. The capping layer 600 may include a filler. Even when the capping layer 600 and the plurality of interconnection modules IM to be described hereinafter include an identical material, due to process order, an interface SF may be formed between the capping layer 600 and the plurality of interconnection modules IM. Even when the capping layer 600 and the chip molding film 500 include an identical substance, due to process order, an interface may be formed between the capping layer 600 and the chip molding film 500.

According to example embodiments, the plurality of interconnection modules IM may include the first interconnection module IM1 which is placed to overlap the first wiring post 121 in the first direction D1, in the first stair area ST1 of the first chip module CM1, the second interconnection module IM2 which is placed to overlap the second wiring post 122 in the first direction D1, in the second stair area ST2 of the second chip module CM2, and the third interconnection module IM3 which is placed to overlap the third wiring post 123 in the first direction D1, in the third stair area ST3 of the third chip module CM3.

According to example embodiments, the plurality of interconnection modules IM may extend by penetrating the capping layer 600 in the first direction D1, and may be configured to electrically connect the package substrate 50 and the first chip module CM1, the second chip module CM2, the third chip module CM3 and the fourth chip module CM4. Each of the plurality of interconnection modules IM may include an interconnection molding film 800 and at least one interconnection post IP extending in the first direction D1 by penetrating the interconnection molding film 800, and that is connected with any one of the first wiring post 121, the second wiring post 122, the third wiring post 123 and the fourth wiring post 124.

According to example embodiments, the interconnection molding film 800 may be surrounded by the capping layer 600. The interconnection molding film 800 may form the interface SF with the capping layer 600. The interconnection molding film 800 may surround the interconnection post IP. The interconnection molding film 800 may be spaced apart from the chip molding film 500. The interconnection molding film 800 may be spaced apart from the chip molding film 500 with a connecting part 900 placed therebetween. The interconnection molding film 800 may include an insulation material. As an example, the interconnection molding film 800 may include an insulating high-polymer material such as an EMC. As another example, the same may include a thermosetting resin such as an epoxy resin, a thermoplastic resin such as polyimide, or a prepreg, ABF, FR-4, BT and an EMC including an inorganic filler or/and a glass fiber. The interconnection molding film 800 may include a filler.

According to example embodiments, the interconnection post IP may be surrounded by the interconnection molding film 800. The interconnection post IP may extend between the package substrate 50 and the first chip module CM1 through the third chip module CM3. The interconnection post IP may be configured to electrically connect the wiring post 120 and the package substrate 50. The interconnection post IP may include a metallic material such as titanium (Ti), copper (Cu), aluminum (Al), silver (Ag), tin (Sn), gold (Au), nickel (Ni), lead (Pb) or an alloy thereof. FIG. 1 illustrates that the interconnection post IP is a single-layered film, but example embodiments are not limited thereto. For example, the interconnection post IP may have a multilayered film structure.

According to example embodiments, the first interconnection module IM1, the second interconnection module IM2 and the third interconnection module IM3 may be placed respectively corresponding to the first stair area ST1, the second stair area ST2 and the third stair area ST3. More specifically, the first interconnection module IM1 may be placed to overlap the first wiring post 121 of the first stair area ST1 in the first direction, the second interconnection module IM2 may be placed to overlap the second wiring post 122 of the second stair area ST2 in the first direction D1, and the third interconnection module IM3 may be placed to overlap the third wiring post 123 of the third stair area ST3 in the first direction D1. According to example embodiments, a number of the interconnection posts IP may be identical to a number of the plurality of wiring posts 120 included in a chip module CM that overlaps the corresponding interconnection post IP in the first direction D1. This may form a one-to-one corresponding relationship between the wiring post 120 and the interconnection post IP to improve reliability of electric connection. In addition, because the interconnection module IM is formed by being separated from the wiring post 120 in each chip module CM, an aspect ratio (AR) of the wiring post 120 or the interconnection module IM may be reduced compared to a case in which the single long wiring post 120 is formed. This may reduce risks in manufacture caused by a high AR which may be generated in a structure in which the plurality of chips (e.g., the first chip 100, the second chip 200, the third chip 300 and the fourth chip 400) are stacked by high stages.

According to example embodiments, at least one of the plurality of interconnection modules IM may have a length in the first direction D1, which is different from lengths of the other interconnection modules. Here, levels of lowest surfaces of the plurality of interconnection modules IM may be identical to one another.

According to example embodiments, the plurality of interconnection modules IM may have lengths in the first direction D1, which are different from one another. More specifically, a first length of the first interconnection module IM1 in the first direction D1 may be longer than a second length of the second interconnection module IM2 in the first direction D1, and the second length of the second interconnection module IM2 in the first direction D1 may be longer than a third length of the third interconnection module IM3.

This may be because the interconnection modules are formed to correspond to each stair area of the chip modules stacked in a stair structure. For instance, the AR of the first interconnection module IM1 may be 15:1 to 20:1, the AR of the second interconnection module IM2 may be 10:1 to 15:1, and the AR of the third interconnection module IM3 may be 5:1 to 10:1, without being limited thereto. In case that the AR of the interconnection module IM is great, by combining the plurality of interconnection modules IM, risks of manufacture caused by a high AR which may be generated in a structure in which the plurality of chips (e.g., the first chip 100, the second chip 200, the third chip 300, and the fourth chip 400) are stacked by high stages may be reduced.

According to example embodiments, levels of lowest surfaces of the plurality of interconnection modules IM are identical to one another, whereas levels of top surfaces thereof may be different from one another. More specifically, levels of top surfaces of a portion of the plurality of interconnection modules IM may be higher than levels of top surfaces of another portion thereof. Such a structure may be formed to correspond to a height of each stair of the chip modules stacked in a stair shape.

According to example embodiments, the connecting part 900 may be placed between the interconnection modules IM and the chip modules CM. According to example embodiments, the connecting part 900 may be placed between a bottom part of the plurality of wiring posts 120 and a top part of the plurality of interconnection modules IM. Specifically, the connecting part 900 may electrically connect a lower surface of the wiring posts 120 and an upper surface of the interconnection post IP. The connecting part 900 may include a bump 910 or a connection pad 920. The bump 910 may include a solder ball or a solder bump. As another example, the bump 910 may include a microbump. The bump 910 may be spherical or ellipsoidal but the same is not limited thereto. The number, spacing, arrangement and shape of the bump 910 are not limited to what is illustrated, and it is apparent that the number, spacing, arrangement and shape may vary depending on a design. The bump 910 may include, for example, tin (Sn), indium (In), bismuth (Bi), antimony (Sb), copper (Cu), silver (Ag), zinc (Zn), lead (Pb) and a combination thereof, without being limited thereto. With regard to the example embodiments hereinafter, difference from what is described with reference to FIG. 1 will be mainly explained for convenience of explanation.

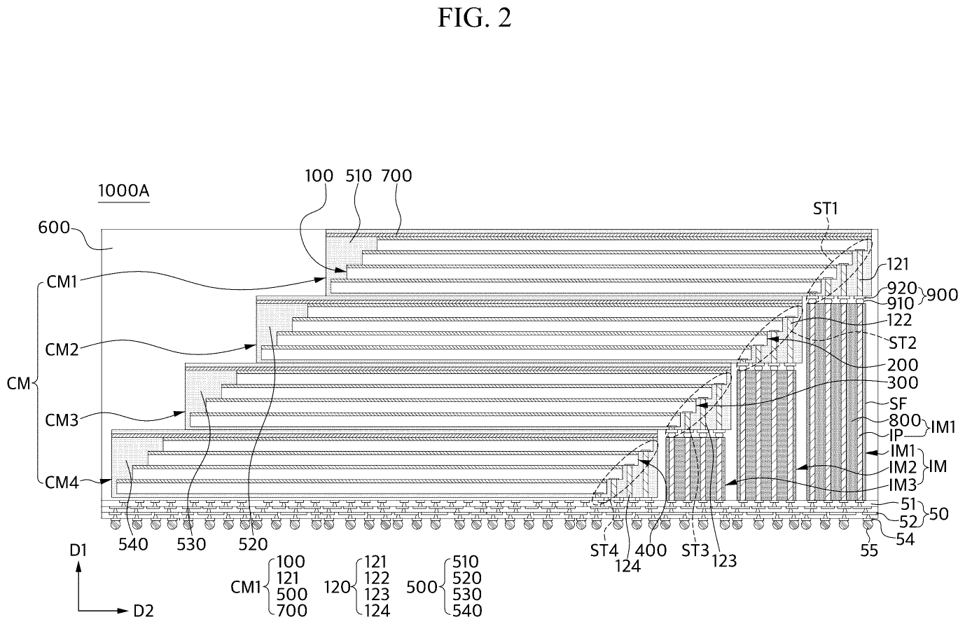

FIG. 2 is a drawing for illustrating a semiconductor package according to example embodiments of the present disclosure.

Referring to FIG. 2, a semiconductor package 1000A may further include the external connection terminal 55 on a back side surface of the package substrate 50. The external connection terminal 55 may be placed on an external connection pad 54. The external connection terminal 55 may be in contact with the external connection pad 54. As an example, the external connection terminal 55 may include a solder ball or a solder bump. As another example, the external connection terminal 55 may include a microbump. The external connection terminal 55 may be spherical or ellipsoidal, but the same is not limited thereto. The number, spacing, arrangement and shape of the external connecting terminal 55 are not limited to what is illustrated, and it is apparent that the number, spacing, arrangement and shape may vary depending on a design. The external connecting terminal 55 may include, for example, tin (Sn), indium (In), bismuth (Bi), antimony (Sb), copper (Cu), silver (Ag), zinc (Zn), lead (Pb) and a combination thereof, without being limited thereto.

According to example embodiments, the external connection terminal 55 may electrically connect the substrate wiring structure 52 and an external device. Accordingly, the external connection terminal 55 may provide an electric signal to the substrate wiring structure 52 or provide, to an external device, an electric signal provided from the substrate wiring structure 52.

For example, the external connection terminal 55 may, by providing an electric signal with respect to the first chip module CM1, the second chip module CM2, the third chip module CM3 and the fourth chip module CM4, provide an electric signal to the first chip module CM1, the second chip module CM2, the third chip module CM3 and the fourth chip module CM4. The external connection terminal 55 may receive a signal that is inputted to the first chip module CM1, the second chip module CM2, the third chip module CM3 and the fourth chip module CM4. The external connection terminal 55 may receive a signal that is outputted by the first chip module CM1, the second chip module CM2, the third chip module CM3 and the fourth chip module CM4.

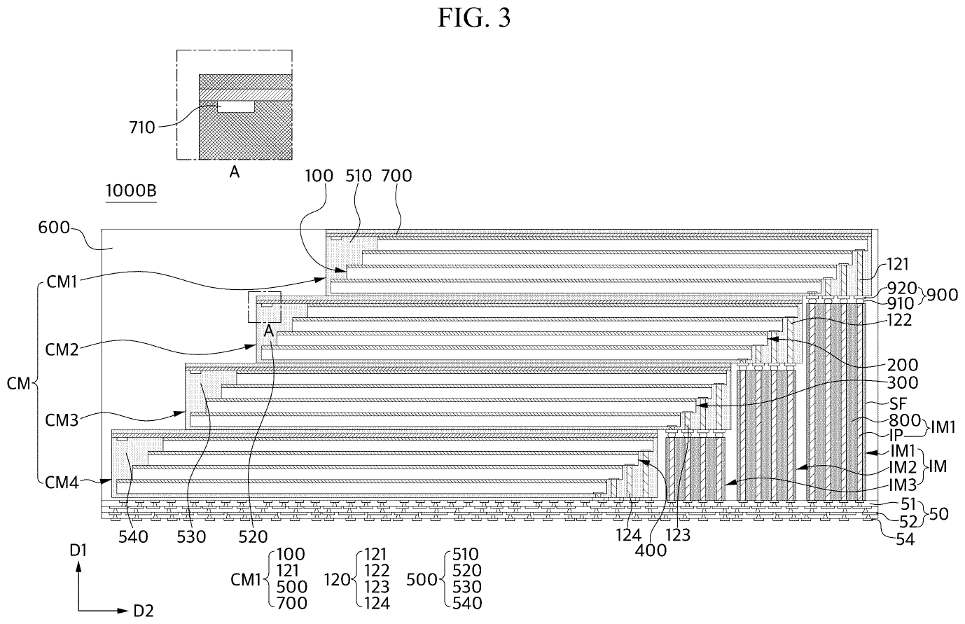

FIG. 3 is a drawing for illustrating a semiconductor package according to example embodiments of the present disclosure.

Referring to FIG. 3, a semiconductor package 1000B may further include an alignment pad 710 in each of the first chip module CM1, the second chip module CM2, the third chip module CM3 and the fourth chip module CM4. According to example embodiments, the alignment pad 710 may be placed in the chip molding film 500 of each of the first chip module CM1, the second chip module CM2, the third chip module CM3 and the fourth chip module CM4. The alignment pad 710 may be covered by the chip molding film 500. Specifically, in the first direction D1, the alignment pad 710 may be placed on the back side surface of the passivation layer 700 facing the package substrate 50. For instance, the alignment pad 710 may be used to align each of the chips (e.g., the first chip 100, the second chip 200, the third chip 300 and the fourth chip 400). Aligning may indicate setting positions around a reference point in order to place in preset positions. The alignment pad 710 may be placed somewhere on the passivation layer 700 or in the semiconductor package 1000B, but may not exist in the semiconductor package 1000B in a process of cutting the chips (e.g., the first chip 100, the second chip 200, the third chip 300 and the fourth chip 400).

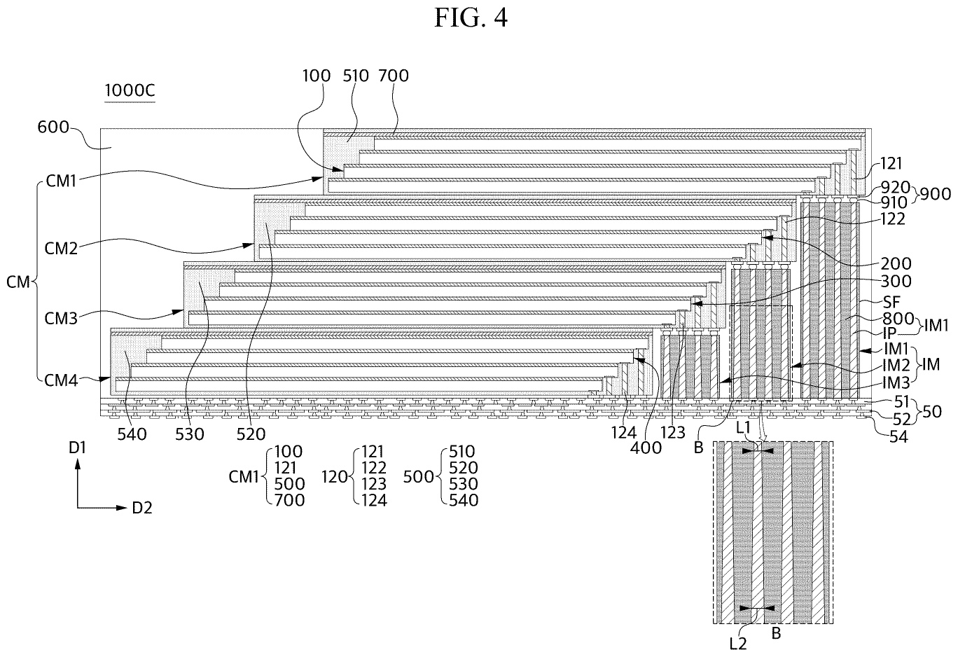

FIG. 4 is a drawing for illustrating a semiconductor package according to example embodiments of the present disclosure.

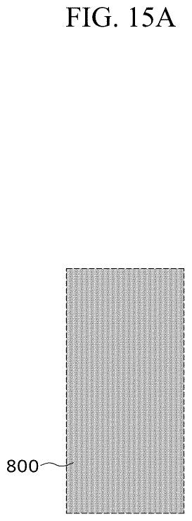

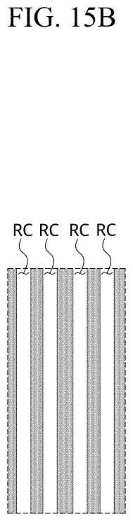

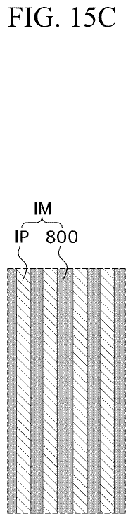

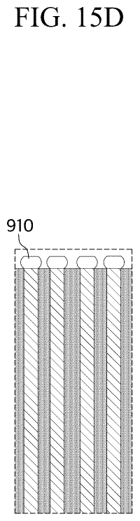

Referring to an area B of FIG. 4, as for a semiconductor package 1000C, unlike the semiconductor package 1000 of FIG. 1, a width L1 in the second direction D2 at a top part of the interconnection post IP may be smaller than a width L2 in the second direction D2 at a bottom part of the interconnection post IP. In other words, as for the interconnection post IP, the width in the second direction D2 may increase in a direction to the front side surface of the package substrate 50. This may be because of having been formed to vary depending on a height of the interconnection molding film 800 in a process of FIGS. 15A-15D which is to be described hereinafter. When a recessed area RC is formed in the process of FIGS. 15A-15D, in the case that a width of a bottom part has become narrower, the bump 910 may be attached to a part at which a width of the interconnection post IP to be described hereinafter becomes narrower before being connected with the first chip module CM1.

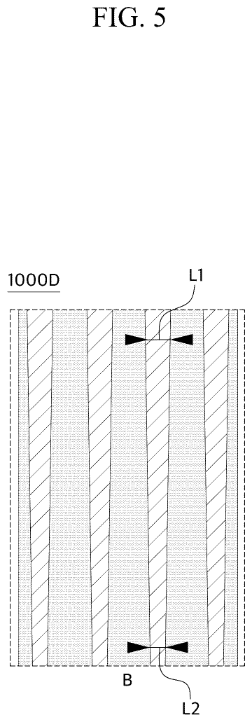

FIG. 5 is an exemplary drawing that illustrates by enlarging example embodiments of the area B of FIG. 4.

FIG. 5 illustrates by enlarging the area B of FIG. 4. Referring to FIG. 5, a semiconductor package 1000D may have a structure different from that of the interconnection post IP of the semiconductor package 1000C of FIG. 4. According to example embodiments, the width L1 in the second direction D2 of the top part of the interconnection post IP may be greater than the width L2 in the second direction D2 of the bottom part of the interconnection post IP. In other words, as for the interconnection post IP, the width in the second direction D2 may be gradually reduced in a direction to the front side surface of the package substrate 50. This may be because of having been formed to vary depending on the height of the interconnection molding film 800 in the process of FIGS. 15A-15D which is to be described hereinafter. When the recessed area RC is formed in the process of FIGS. 15A-15D, in the case that a width of a bottom part has become narrower, the bump 910 may be attached to a part (a part in which a width of the interconnection post IP increases) which is opposite to the part at which a width of the interconnection post IP to be described hereinafter becomes narrower before being connected with the first chip module CM1.

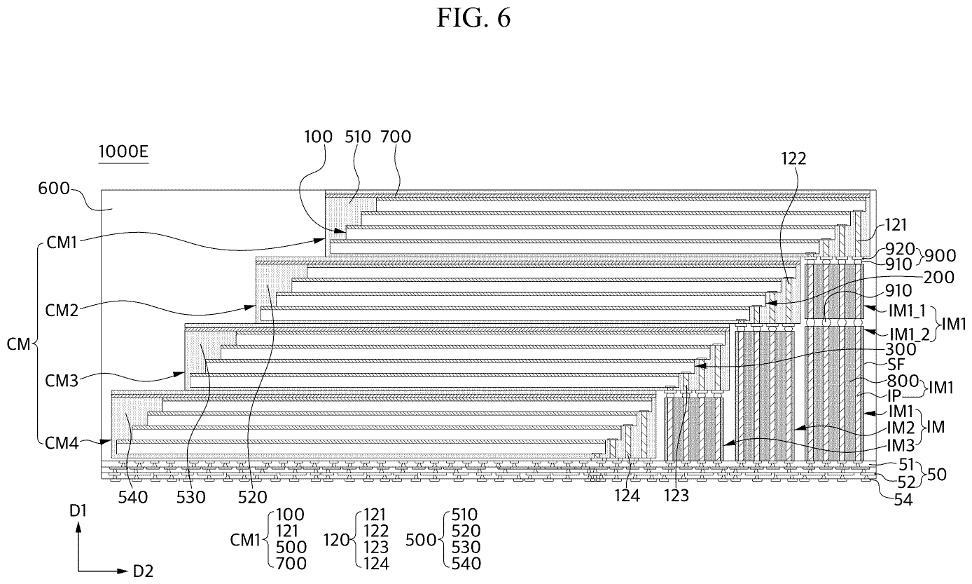

FIG. 6 is a drawing for illustrating a semiconductor package according to example embodiments of the present disclosure.

Referring to FIG. 6, the first interconnection module IM1 of a semiconductor package 1000E may include a first module part IM1_1 and a second module part IM1_2 which overlap one another in the first direction D1 in the first stair area ST1. Here, between the first module part IM1_1 and the second module part IM1_2, the bump 910 of the connecting part 900 may be placed. According to example embodiments, a length of the first module part IM1_1 in the first direction D1 may be substantially identical to a length of the third interconnection module IM3 in the first direction D1. This may be because the third interconnection module IM3 and the first module part IM1_1 are manufactured by a substantially identical process, without being limited thereto. Likewise, a length of the second module part IM1_2 in the first direction D1 may be substantially identical to a length of the second interconnection module IM2 in the first direction D1. This may be because the second interconnection module IM2 and the second module part IM1_2 are manufactured by a substantially identical process, without being limited thereto. Therefore, unlike the semiconductor package 1000 of FIG. 1 in which the first interconnection module IM1, the second interconnection module IM2 and the third interconnection module IM3, which have lengths in the first direction D1 different from one another, are manufactured to be different from one another, the semiconductor package 1000E of FIG. 6 may simultaneously manufacture the first module part IM1_1 and the second module part IM1_2 of the first interconnection module IM1 while performing a process of manufacturing the second interconnection module IM2 and the third interconnection module IM3, thereby reducing difficulty in process. Further, the AR of the interconnection module IM may be reduced, and therefore, risks of manufacture caused by a high AR which may be generated in a structure in which the plurality of chips (e.g., the first chip 100, the second chip 200, the third chip 300 and the fourth chip 400) are stacked by high stages may be reduced.

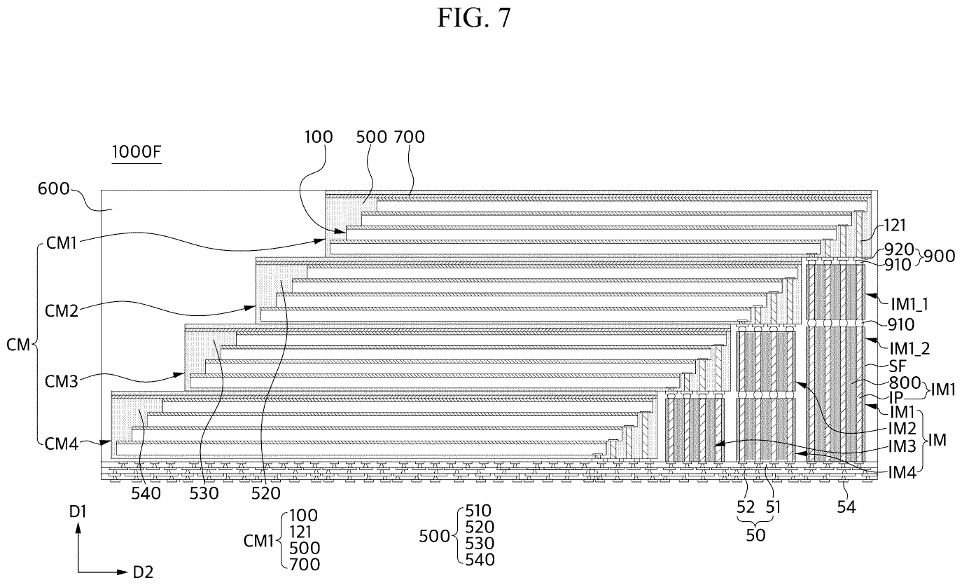

FIG. 7 is a drawing for illustrating a semiconductor package according to example embodiments of the present disclosure.

Referring to FIG. 7, a semiconductor package 1000F may further include a fourth interconnection module IM4 between the second interconnection module IM2 and the front side surface of the package substrate 50, in the second stair area ST2 of the second chip module CM2. Between the second interconnection module IM2 and the fourth interconnection module IM4, the bump 910 of the connecting part 900 may be placed.

According to example embodiments, a length of the second interconnection module IM2 in the first direction D1 may be substantially identical to a length of each of the third interconnection module IM3 and the fourth interconnection module IM4 in the first direction D1. This may be because the second interconnection module IM2 and the fourth interconnection module IM4 are manufactured together in a process substantially identical to a process of manufacturing the third interconnection module IM3. The first module part IM1_1 of the first interconnection module IM1 may be substantially identical to a length of the third interconnection module IM3 in the first direction D1.

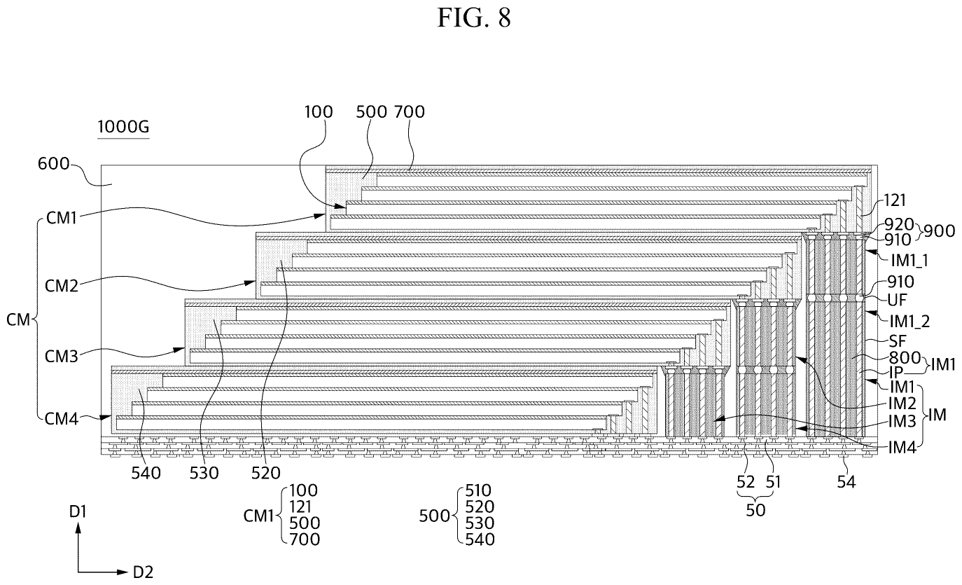

FIG. 8 is a drawing for illustrating a semiconductor package according to example embodiments of the present disclosure.

Referring to FIG. 8, a semiconductor package 1000G may further include under-filling resin UF which is used to, in the semiconductor package 1000F of FIG. 7, fill a space between the first chip module CM1 and the first interconnection module IM1, fill a space between the second chip module CM2 and the second interconnection module IM2, and fill a space between the third chip module CM3 and the third interconnection module IM3. According to example embodiments, the under-filling resin UF may be placed to surround the connecting part 900. The under-filling resin UF may perform a function of improving mechanical stability of the connecting part 900 and protecting the same from the external environment. The under-filling resin may be molded under-filling (MUF) or capillary under-filling (CUF).

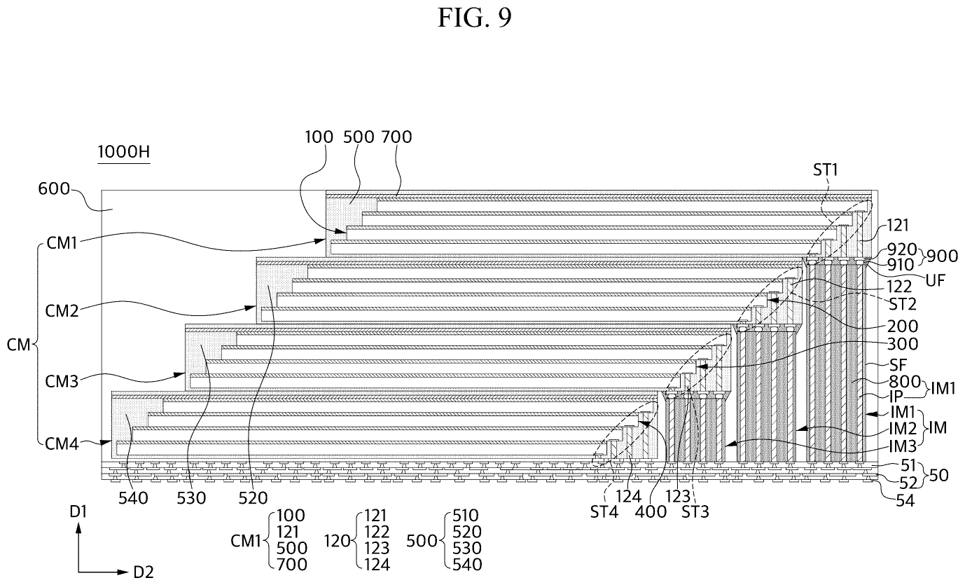

FIG. 9 is a drawing for illustrating a semiconductor package according to example embodiments of the present disclosure.

With regard to the example embodiment of FIG. 9, differences from what is described with reference to FIG. 1 will be mainly explained for convenience of explanation.

Referring to FIG. 9, a semiconductor package 1000H may further include the under-filling resin UF which is used to, in the semiconductor package 1000 of FIG. 1, fill a space between the first chip module CM1 and the first interconnection module IM1, fill a space between the second chip module CM2 and the second interconnection module IM2, and fill a space between the third chip module CM3 and the third interconnection module IM3. According to example embodiments, the under-filling resin UF may be placed to surround the connecting part 900. The under-filling resin UF may perform a role of improving mechanical stability of the connecting part 900 and protecting the same from the external environment. The under-filling resin may be MUF or CUF.

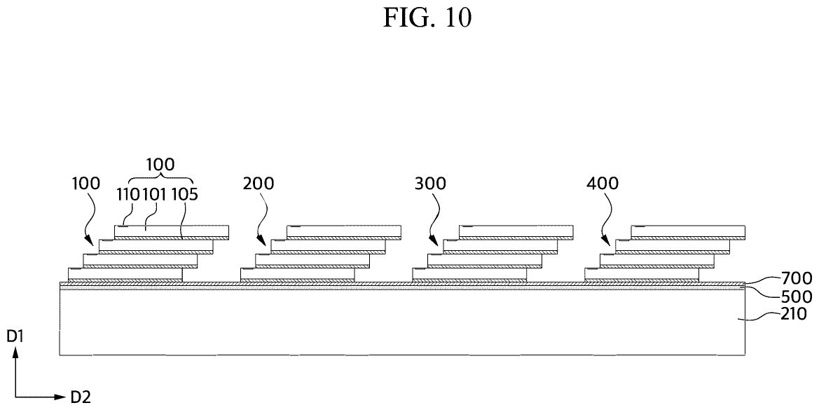

FIGS. 10 to 18 are drawings illustrating, in a process order, examples of a manufacturing method of a semiconductor package according to example embodiments of the present disclosure.

Referring to FIG. 10, the first chip 100, the second chip 200, the third chip 300 and the fourth chip 400 may be stacked in a stair structure on a base substrate 210. The base substrate 210 serves to support chips in the following processes, and may be constituted with various materials such as silicone, glass and ceramic. When the first chip 100, the second chip 200, the third chip 300 and the fourth chip 400 are stacked, precise position alignment of each chip is important, and for this, the alignment pad 710 of FIG. 2 may be utilized. The alignment pad 710 may be formed on the passivation layer 700, or placed at another area of a semiconductor package in order to precisely control the position of the chip. Because the first chip 100, the second chip 200, the third chip 300 and the fourth chip 400 are placed by being offset with one another at the stair areas (e.g., the first stair area ST1, the second stair area ST2, the third stair area ST3 and the fourth stair area ST4) in the second direction D2, the connection pad 110 of each chip may not overlap another chip. By using the adhesive layer 105, each chip may be solidly fixed on the base substrate 210 or on a lower chip.

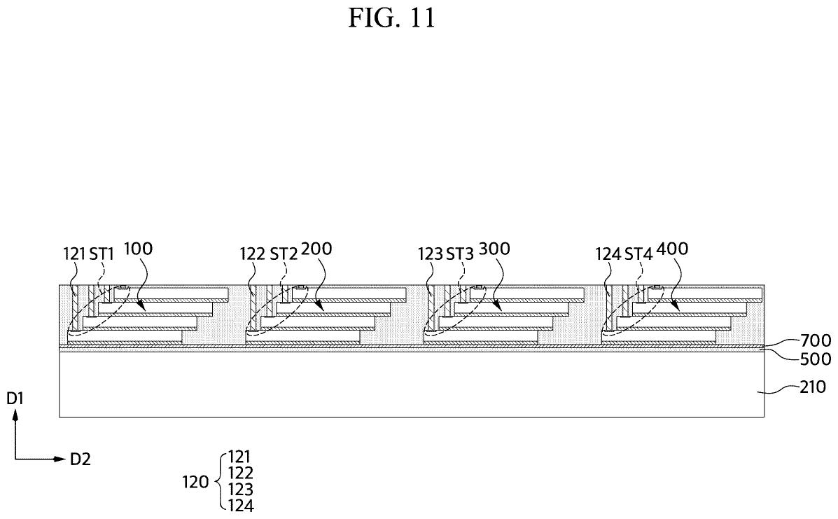

Referring to FIG. 11, the chip molding film 500 surrounding the plurality of wiring posts 120 and the plurality of chips (e.g., the first chip 100, the second chip 200, the third chip 300 and the fourth chip 400) may be formed. For example, after the chip molding film 500 surrounding the plurality of chips (e.g., the first chip 100, the second chip 200, the third chip 300 and the fourth chip 400) is formed, the plurality of wiring posts (e.g., the first wiring post 121, the second wiring post 122, the third wiring post 123 and the fourth wiring post 124) may be formed to correspond to each of the plurality of chips (e.g., the first chip 100, the second chip 200, the third chip 300 and the fourth chip 400) at the stair areas (e.g., the first stair area ST1, the second stair area ST2, the third stair area ST3 and the fourth stair area ST4) which are one side of the plurality of chips (e.g., the first chip 100, the second chip 200, the third chip 300 and the fourth chip 400). The wiring post 120 may be formed on the connection pad 110 of each chip by using a method such as sputtering, plating and chemical vapor deposition (CVD). Specifically, after forming a recessed space in which the wiring post 120 is to be formed by etching the chip molding film 500, a material of the wiring post 120 may be filled in the recessed space to form the wiring post 120. The wiring post 120 may be electrically connected with the connection pad 110 of each of the first chip 100, the second chip 200, the third chip 300 and the fourth chip 400, and may be formed by penetrating the chip molding film 500 in the first direction D1, without being limited thereto.

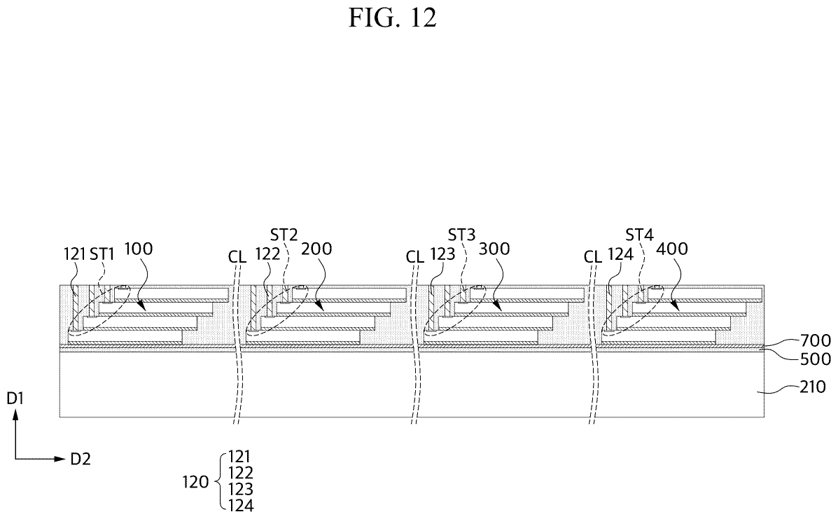

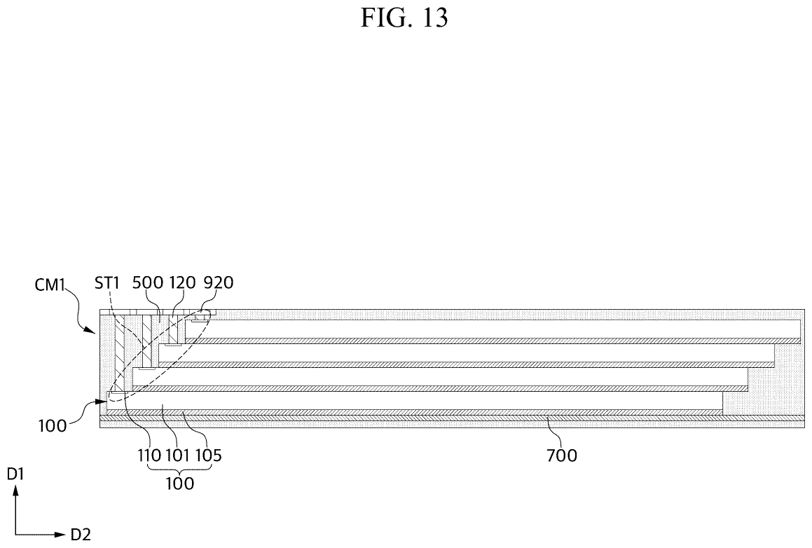

Referring to FIG. 12 and FIG. 13, the connection pad 920 may be formed on the plurality of chip modules (e.g., the first chip module CM1, the second chip module CM2, the third chip module CM3 and the fourth chip module CM4), and then the plurality of chip modules (e.g., the first chip module CM1, the second chip module CM2, the third chip module CM3 and the fourth chip module CM4) including the plurality of chips (e.g., the first chip 100, the second chip 200, the third chip 300 and the fourth chip 400), the plurality of wiring posts 120 and the chip molding film 500 may be cut from the base substrate 210, without being limited thereto. The plurality of chip modules (e.g., the first chip module CM1, the second chip module CM2, the third chip module CM3 and the fourth chip module CM4) may be formed by means of cutting along a cut line CL.

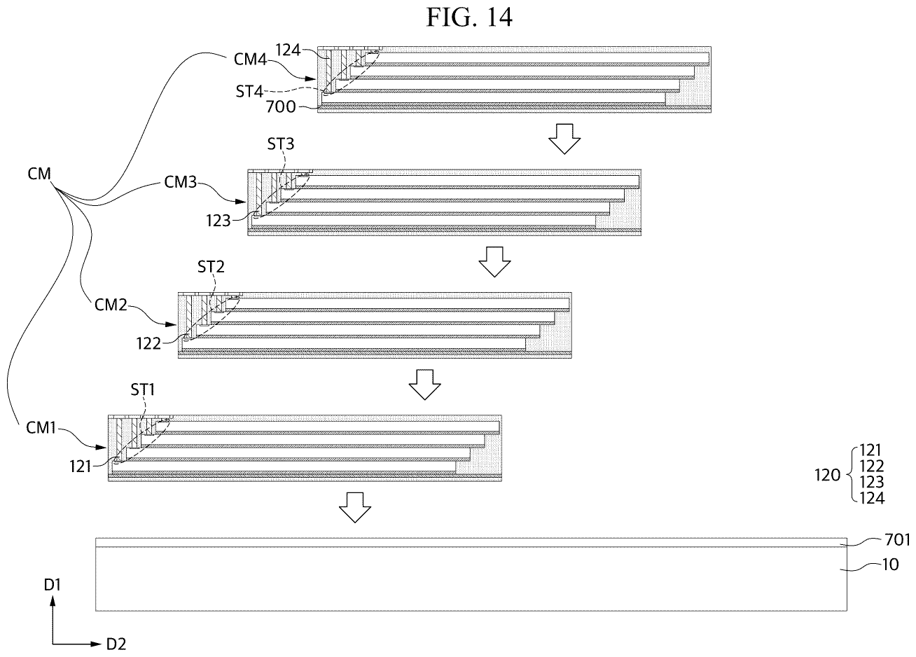

Referring to FIG. 14, the plurality of chip modules (e.g., the first chip module CM1, the second chip module CM2, the third chip module CM3 and the fourth chip module CM4) may be stacked in a stair structure on the carrier substrate 10. First, a pre-adhesive layer 701 may be applied on the carrier substrate 10, and then the plurality of chip modules (e.g., the first chip module CM1, the second chip module CM2, the third chip module CM3 and the fourth chip module CM4) may be stacked. The pre-adhesive layer 701 may aid the stacking of the chip modules CM in the following processes. An alignment pad 750 may be included in the pre-adhesive layer 701, but the same is not limited thereto.

FIGS. 15A through 15D illustrate a process of forming an interconnection module IM, and may be configured with the following detailed operations.

Referring to FIG. 15A, the interconnection molding film 800 may be firstly formed. The interconnection molding film 800 may be formed by using a method such as sputtering and CVD. The interconnection molding film 800 may perform a role of supporting and protecting the interconnection post IP which is to be formed in the following processes.

Referring to FIG. 15B, the recessed area RC penetrating the interconnection molding film 800 may be formed. The recessed area RC may be formed by removing a part of the interconnection molding film 800 by using an etching process and the like.

Referring to FIG. 15C, the interconnection post IP may be formed on the recessed area RC. The interconnection post IP may be formed by using a method such as plating and sputtering, and may be electrically connected with the wiring post 120 in the following processes. Generally, a metallic material such as copper (Cu) may be used for the interconnection post IP.

Referring to FIG. 15D, the bump 910 may be selectively attached to an upper surface or a lower surface of the interconnection post IP. A solder bump, a microbump and the like may be used for the bump 910, and the bump 910 may perform a role of facilitating ease in electric connection between the chip module and the package substrate 50 in the following processes. By polishing the interconnection module IM or setting a length of the interconnection molding film 800 in the first direction, a length of the first interconnection module IM1 through the fourth interconnection module IM4 in the first direction may be adjusted.

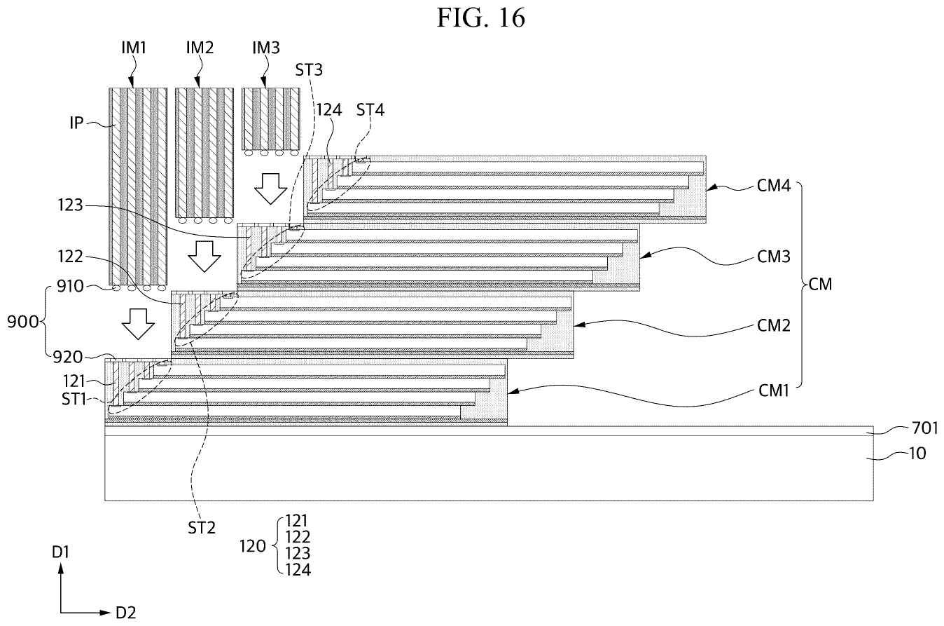

Referring to FIG. 16, after the interconnection module IM is formed, the interconnection module IM may be placed to overlap at least a portion of the plurality of wiring posts 120 in the first stair area ST1, the second stair area ST2 and the third stair area ST3 on the plurality of chip modules (e.g., the first chip module CM1, the second chip module CM2 and the third chip module CM3) in the first direction D1. In order to connect the interconnection module IM and the plurality of chip modules (e.g., the first chip module CM1, the second chip module CM2 and the third chip module CM3) by means of the connecting part 900, heat may be applied for connection.

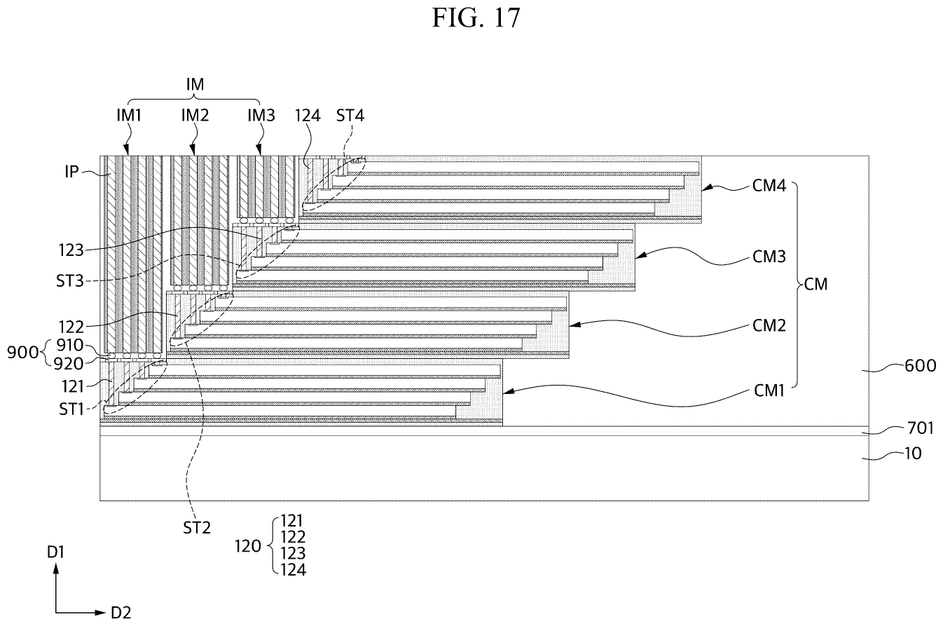

Referring to FIG. 17, the capping layer 600 which surrounds each of the plurality of chip modules (e.g., the first chip module CM1, the second chip module CM2, the third chip module CM3 and the fourth chip module CM4) and the plurality of interconnection modules IM may be formed, and a flattening process may be performed.

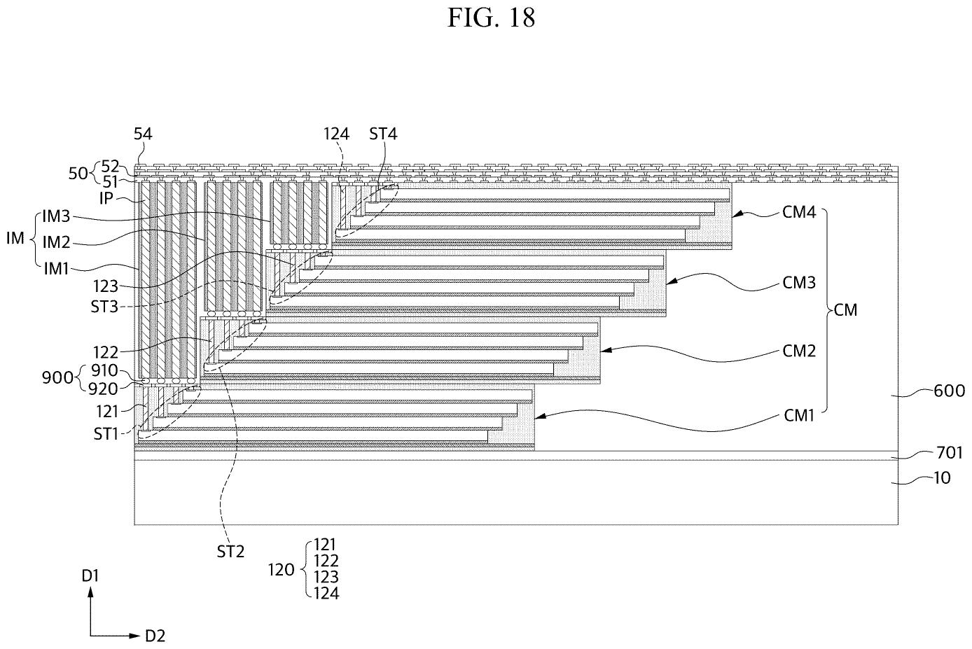

Referring to FIG. 18, the package substrate and the external connection pad 54 may be formed on the plurality of chip modules (e.g., the first chip module CM1, the second chip module CM2, the third chip module CM3 and the fourth chip module CM4), the plurality of interconnection modules IM, and the capping layer 600.

Next, the carrier substrate 10 and the pre-adhesive layer 701 may be removed in order for the semiconductor package 1000 of FIG. 1 to be formed.

According to example embodiments, it is possible to manufacture a semiconductor package by modularizing the same to perform a process by each module unit, thereby minimizing risks in manufacture even when a semiconductor chip is stacked by high stages of 16 stages or more.

According to example embodiments, it is possible to form an interconnection post for each module so as to reduce an aspect ratio (AR) of the interconnection post required by a semiconductor package, thereby facilitating ease in manufacture.

While various example embodiments of the present disclosure are described in detail above, the scope of the present disclosure is not limited thereto, and it will be apparent to those of ordinary skill in the art that various modifications and variations may be made without departing from the technical idea of the present disclosure as defined by the appended claims. In addition, the aforementioned example embodiments may be implemented with some elements removed, and each example embodiment may be implemented in combination with one another.

What is claimed is:

1. A semiconductor package comprising:
a package substrate;
a plurality of chip modules stacked in a stair structure on the package substrate in a first direction perpendicular to a front side surface of the package substrate;
a capping layer surrounding the plurality of chip modules; and
a plurality of interconnection modules extending in the first direction by penetrating the capping layer on back side surfaces of the plurality of chip modules, and configured to electrically connect the package substrate and at least one of the plurality of chip modules,
wherein each of the plurality of interconnection modules comprises:
an interconnection molding film surrounded by the capping layer; and
a plurality of interconnection posts penetrating the interconnection molding film, and
wherein each of the plurality of chip modules comprises a plurality of chips stacked in a stair structure.

2. The semiconductor package of claim 1, wherein an interface is formed between the interconnection molding film and the capping layer.

3. The semiconductor package of claim 1, further comprising a connecting part between the plurality of chip modules and the interconnection module,
wherein the connecting part is a bump or a pad.

4. The semiconductor package of claim 3, further comprising under-filling resin that surrounds the connecting part and is used to fill spaces between the plurality of chip modules and the plurality of interconnection modules.

5. The semiconductor package of claim 1, wherein each of the plurality of chip modules further comprises:
a chip molding film surrounding the plurality of chips; and
a plurality of wiring posts extending in the first direction by penetrating the chip molding film, and electrically connected with the plurality of chips.

6. The semiconductor package of claim 1, wherein each of the plurality of chip modules further comprises a passivation layer on a front side surface of a chip located on a top portion among the plurality of chips, and
wherein at least one of the plurality of chip modules further comprises an alignment pad that is placed on a back side surface of the passivation layer facing the package substrate at one side of the plurality of chips.

7. The semiconductor package of claim 5, wherein a number of the interconnection posts is equal to a number of the plurality of wiring posts included in the chip module that overlaps the interconnection post in the first direction.

8. The semiconductor package of claim 1, wherein at least one of the plurality of interconnection modules has a different length than that of another interconnection module.

9. A semiconductor package comprising:
a package substrate;
a first chip module to a fourth chip module stacked in a stair structure on the package substrate in a first direction perpendicular to a front side surface of the package substrate;
a capping layer surrounding the first chip module, a second chip module, a third chip module and the fourth chip module; and
a plurality of interconnection modules extending in the first direction by penetrating the capping layer, and that are configured to electrically connect the package substrate and each of the first chip module to the fourth chip module,
wherein the first chip module comprises at least one first chip placed to be spaced apart from the package substrate in the first direction perpendicular to the front side surface of the package substrate, a first chip molding film surrounding the first chip, and a first wiring post penetrating the first chip molding film in the first direction and connected with the first chip,
wherein the second chip module comprises at least one second chip placed on a back side surface of the first chip module and placed between the package substrate and the first chip module, a second chip molding film surrounding the second chip, and a second wiring post penetrating the second chip molding film in the first direction and connected with the second chip,
wherein the third chip module comprises at least one third chip placed on a back side surface of the second chip module and placed between the package substrate and the second chip module, a third chip molding film surrounding the third chip, and a third wiring post penetrating the third chip molding film in the first direction and connected with the third chip, and
wherein the fourth chip module comprises at least one fourth chip placed on a back side surface of the third chip module and placed between the package substrate and the third chip module, a fourth chip molding film surrounding the fourth chip, and a fourth wiring post penetrating the fourth chip molding film in the first direction and connected with the fourth chip.

10. The semiconductor package of claim 9, wherein an interface is formed between the plurality of interconnection modules and the capping layer.

11. The semiconductor package of claim 9, wherein the first wiring post to the fourth wiring post are electrically connected with each of the first chip to the fourth chip in a first stair area to a fourth stair area which are one side of each of the first chip module to the fourth chip module.

12. The semiconductor package of claim 11, wherein each of the plurality of interconnection modules comprises:
an interconnection molding film that is in contact with the capping layer; and
at least one interconnection post extending in the first direction by penetrating the interconnection molding film, and that is connected with any one of the first wiring post, the second wiring post, the third wiring post and the fourth wiring post.

13. The semiconductor package of claim 12, wherein the plurality of interconnection modules comprise:
a first interconnection module placed to overlap the first wiring post in the first direction, in the first stair area of the first chip module;
a second interconnection module placed to overlap the second wiring post in the first direction, in a second stair area of the second chip module; and
a third interconnection module placed to overlap the third wiring post in the first direction, in a third stair area of the third chip module.

14. The semiconductor package of claim 13, wherein the first interconnection module has a first length in the first direction that is greater than a second length of the second interconnection module in the first direction, and
wherein the second length of the second interconnection module is greater than a third length of the third interconnection module in the first direction.

15. The semiconductor package of claim 13, wherein the first interconnection module comprises a first module part and a second module part that overlap one another in the first direction in the first stair area.

16. The semiconductor package of claim 15, further comprising a connecting part between the first module part and the second module part in the first stair area.

17. The semiconductor package of claim 15, wherein the plurality of interconnection modules further comprise a fourth interconnection module between the second interconnection module and the front side surface of the package substrate, in the second stair area of the second chip module.

18. The semiconductor package of claim 9, further comprising:
a connecting part between a bottom part of the plurality of wiring posts and a top part of the plurality of interconnection modules; and
under-filling resin that surrounds the connecting part and is used to fill spaces between the first chip module, the second chip module, the third chip module and the fourth chip module and each of the plurality of interconnection modules.

19. A semiconductor package comprising:
a package substrate;
a first chip module to a fourth chip module stacked in a stair structure on the package substrate in a first direction perpendicular to a front side surface of the package substrate;
a capping layer surrounding the first chip module to the fourth chip module; and
a plurality of interconnection modules extending in the first direction by penetrating the capping layer on a back side surface of each of the first chip module to a third chip module, and configured to electrically connect the package substrate and the first chip module to the third chip module,
wherein at least one of the plurality of interconnection modules has a length in the first direction that is different from a length of each of a portion of the plurality of interconnection modules, and
wherein levels of lowest surfaces of the plurality of interconnection modules are identical.

20. The semiconductor package of claim 19, wherein levels of top surfaces of a portion of the plurality of interconnection modules are higher than levels of top surfaces of another portion of the plurality of interconnection modules.
